(19) United States
(12) Patent Application Publication
(10) Pub. No.: US 2016/0126705 A1
(43) Pub. Date: May 5, 2016

(54) ELECTRICAL SERVICE PANEL ASSEMBLY

(71) Applicant: Griffin Electric, Inc., Sacramento, CA (US)

(72) Inventor: Dan A. Griffin, Sacramento, CA (US)

(21) Appl. No.: 14/532,984

(22) Filed: Nov. 4, 2014

(51) Int. Cl. H02B 1/04; H05K 13/00

(52) U.S. Cl. CPC H02B 1/04; H05K 13/0023

(57) ABSTRACT

One embodiment of the present invention is an electrical panel. The electrical panel includes a panel can assembly with a housing configured to house electrical components including a plurality of circuit breakers. The housing includes a plurality of openings serving as utility feed entrances. The openings include a bottom left feed opening, a bottom center feed opening, a top left feed opening, and a top center feed opening to accommodate overhead and underground feeds. The panel can assembly includes a utility area barrier that separates utility wiring from branch circuits and circuit breakers. The panel can assembly also includes a distribution panel cover that is mounted at least two inches away from the housing to provide space for an elevated busbar, thereby allowing utility wires entering the top center feed opening to extend under the elevated busbar toward a meter socket.

### BACKGROUND

1. Field

The present disclosure relates generally to an electrical service panel assembly. More specifically, the present disclosure relates to a universal electrical service panel assembly that an electrician can use in a variety of installation scenarios.

2. Related Art

An electrical service panel is the main distribution center of a building's electricity. The electrical panel is typically a metallic box that holds multiple circuit breakers wired to distribute power throughout the home. Electricity comes into the house through wires connected to the electrical panel. The local electrical utility's service lines connect to the electrical panel, and the electrical panel connects to the individual circuits that run throughout the house. The electrical panel facilitates the distribution of power throughout the home and disconnects power from the incoming feed when necessary. The circuit breakers in the electrical panel can interrupt the flow of electric current when there is a sudden overload. The electrical panel is also called a circuit breaker panel, breaker box, fuse box, service panel, or breaker panel.

There are many types of buildings and dwellings with different requirements for the installation of electrical panels. Currently, one cannot use the electrical panels available on the market in all situations. Electricians must carry multiple varieties of electrical panels to their job site, and choose from the many different types of electrical panels that they carry. For example, some installation sites may have underground feeds, while other installation sites may have overhead feeds. These feeds are the incoming wires that provide electrical service to the building. Electricians must carry different electrical panels to accommodate the different types of feeds. Requiring electricians to carry multiple types of electrical panels is inconvenient. Electricians must search for an electrical panel that will fit the installation needs of a particular job, which is a waste of time and other resources.

### SUMMARY

One embodiment of the present invention is an electrical panel that includes a housing configured to house one or more electrical components, including a plurality of circuit breakers. The plurality of openings serves as utility feed entrances. The openings are positioned on the housing so as to allow for one or more electrical service wiring to enter the housing. This includes at least a bottom left feed opening, a bottom center feed opening, a top left feed opening, and a top center feed opening. The top left feed opening and the bottom left feed opening are each positioned on opposite sidewalls of the housing, and the top center feed opening and bottom center feed opening are likewise each positioned on opposite sidewalls of the housing.

In a variation on this embodiment, the electrical panel includes a top utility access defined by a plurality of interior walls, including a dividing wall disposed so as to form an angle with a wall parallel to a sidewall disposed along the length of the electrical panel.

In a further variation, the angle is approximately 45 degrees.

In a variation on this embodiment, the electrical panel includes a distribution panel cover that is mounted at least two inches away from the housing to allow for installation of an elevated busbar.

In a variation on this embodiment, the electrical panel includes a utility area barrier that separates the utility feed from a load center space for holding branch circuits and/or circuit breakers. The utility area barrier includes an opening to allow extending a utility feed from the bottom center feed opening to a utility area where a meter socket is located.

In a variation on this embodiment, the bottom center feed opening is part of a bottom utility access, and separated from a load center space for holding branch circuits and/or circuit breakers by an interior wall fastened to a utility area barrier and a sidewall of the housing.

In a variation on this embodiment, the electrical panel includes a raceway to allow the one or more electrical service wiring to extend through the housing from one of the two openings on the top sidewall, or from one of the two openings on the bottom sidewall, to a meter socket.

In a variation on this embodiment, the electrical panel is capable of being semi-flush mounted or surface mounted.

In a variation on this embodiment, the top left feed opening is aligned with the bottom left feed opening such that a line drawn between the center of the two openings is substantially parallel to a left sidewall or a right sidewall of the housing.

In a variation on this embodiment, the top center feed opening is aligned with the bottom center feed opening such that a line drawn between the center of the two openings is substantially parallel to a left sidewall or a right sidewall of the housing.

In a variation on this embodiment, the electrical panel has no other openings on sidewalls except for the top left feed opening, the top center feed opening, the bottom center feed opening, and the bottom left feed opening.

Another embodiment of the present invention is a method for assembling an electrical panel. The method includes providing a housing configured to house one or more electrical components, including a plurality of circuit breakers. Next, the method creates a plurality of openings on the housing. The plurality of openings serves as utility feed entrances. The openings are positioned on the housing so as to allow for one or more electrical service wiring to enter the housing. This includes at least a bottom left feed opening, a bottom center feed opening, a top left feed opening, and a top center feed opening. The top left feed opening and the bottom left feed opening are each positioned on opposite sidewalls of the housing, and the top center feed opening and bottom center feed opening are likewise each positioned on opposite sidewalls of the housing.

### BRIEF DESCRIPTION OF THE FIGURES

FIG. 1 illustrates a perspective view of a panel can assembly without covers, in accordance with an embodiment of the present invention.

FIG. 2 presents a plan view of the panel can assembly with side and end elevations, in accordance with an embodiment of the present invention.

FIG. 3 presents a plan view of a utility area barrier with side and end elevations, in accordance with an embodiment of the present invention.

FIG. 4 presents a plan view of an assembled top utility access with side and end elevations, in accordance with an embodiment of the present invention.

FIG. 5 presents a perspective view of an exploded top utility access with plan view and elevations of two parts, in accordance with an embodiment of the present invention.

FIG. 6 presents a plan view of an assembled bottom utility access with side and end elevations, in accordance with an embodiment of the present invention.

FIG. 7 presents a rotated, exploded perspective view of a bottom utility access with plan view and elevations of two parts, in accordance with an embodiment of the present invention.

FIG. 8 presents a plan view of a distribution panel cover with mounting brackets, with plan view and elevations of two parts, in accordance with an embodiment of the present invention.

FIG. 9 presents a flowchart illustrating a process of assembling an electrical panel, in accordance with an embodiment of the present invention.

In the figures, like reference numerals refer to the same figure elements.

### DETAILED DESCRIPTION

### Overview

Embodiments of the present invention solve the problem of requiring electricians to carry multiple types of electrical panels to job sites by providing a universally adaptable electrical panel assembly that can accommodate different installation situations. The electrical panel assembly includes a flexible design that allows for utility feeds to enter the electrical panel through different openings at the top or the bottom of the electrical panel. The design of the electrical panel allows for accommodating an overhead left feed, an overhead center feed, an underground left feed, and/or an underground center feed. The utility feeds can be electrical wiring that carries electrical power for service to a building.

The electrical panel may be surface mounted or semi-flush mounted, with any combination of utility feed configurations. It is sufficiently large for 42 or more circuit breakers, with a built-in surge protector, and a generator feed, even when it is semi-flush mounted. As described herein, a housing and a distribution panel cover of the electrical panel is referred to together as a panel can assembly.

The panel can assembly is versatile so that electricians need not search for a specific panel can assembly that can fit the particular installation needs of a building. Instead, an electrician can store one type of panel can assembly in his van that he can immediately use in any situation, saving time that would otherwise be spent searching for a panel can assembly that will fit a particular installation.

Utility wires carrying electricity enter the panel can assembly through one or more openings on the panel can assembly. The top of the panel can assembly includes multiple openings for the utility feed to enter the panel can assembly. In one implementation, the panel can assembly includes a top utility access that the utility feed can extend through and down to an electrical meter. The openings on the top of the panel can assembly include a top left feed opening and a top center feed opening. The bottom of the panel can assembly may also include multiple openings for the utility feed to enter the panel can assembly, including a bottom left feed opening and a bottom utility access with a bottom center feed opening. Note that the utility feed can also be, or can be referred to as, electrical service wiring, electrical wiring, service entrance conduit, service entry wire, or electrical conduit.

The panel can assembly also includes a utility area barrier to separate utility wiring in a raceway from circuit breakers and branch circuit wiring. The incoming electrical utility feed at the bottom utility access may be extended through the utility area barrier to be connected to a meter socket. The utility feed from the top of the panel can assembly may also be extended through the raceway to be connected to the meter socket. Note that the panel can assembly described herein is a combination panel that combines the meter with the circuit breakers in a single unit.

The panel can assembly also includes a distribution panel cover that can be attached to the housing with mounting brackets, and space for a load center that holds circuit breakers and branch circuits. The distribution panel cover is mounted at least two inches away from the housing using the mounting brackets, thereby allowing for one or more busbars to be raised. The elevated busbar(s) allow for the utility feed to enter through the top center feed opening and extend toward the meter socket via a channel underneath the busbar(s).

### Overview of Panel can Assembly

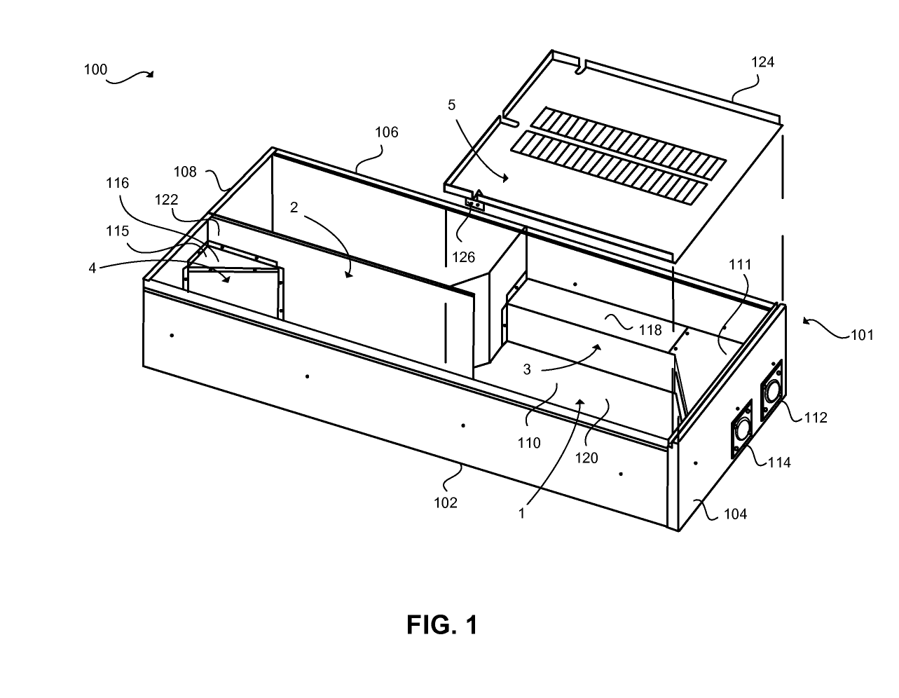

FIG. 1 illustrates a perspective view of a panel can assembly 100 without covers, in accordance with an embodiment of the present invention. FIG. 1 illustrates five major parts of panel can assembly 100 with improvements. Part 1 is space for a load center that can hold the circuit breakers and branch circuits. Part 2 is a utility area barrier that separates a utility wiring raceway from an area for a load center that can hold circuit breakers and branch circuits. Part 3 is a top utility access and also forms part of the raceway. Part 4 is a bottom utility access and is also part of the raceway. Part 5 is a distribution panel cover. Below are details that describe the various components of panel can assembly 100. Note that the figures may have small circular markings that indicate where a screw, bolt, rivet, and/or other fastener can be inserted to fasten parts together.

As depicted in FIG. 1, panel can assembly 100 includes a housing 101 with sidewalls 102-108 that are perpendicular to base 110 and define an interior 111 of the panel can assembly 100. Sidewall 104 forms a top and sidewall 108 forms a bottom of the panel can assembly 100. Housing 101, including sidewalls 102-108, may be constructed from steel. Sidewalls 102-108 are substantially smooth and planar except where there are openings.

Panel can assembly 100 can house circuit breakers, utility wiring, switches, and other electrical components. Within interior 111 of the panel can assembly 100 are a number of partitioned sections. Panel can assembly 100 includes a raceway 118 and a load center space 120. Raceway 118 isolates utility wiring from other wiring and protects the utility wiring. Raceway 118 forms a physical pathway for electrical wiring within the electrical panel. Load center space 120 allows for a load center that houses multiple circuit breakers, with the multiple circuit breakers being connected to two hot busbars. The hot busbars would be connected to a main circuit breaker that connects to two hot utility feeds. Each circuit breaker would be connected to a branch circuit. Branch circuits leave the electrical panel to power electrical devices, such as lighting fixtures and washing machines. Utility area barrier 122 separates utility wiring from the branch circuits and circuit breakers when the branch circuits and circuit breakers are installed.

There are at least four available utility feed openings on the panel can assembly 100. In some implementations, at the top of the panel can assembly 100 there are two utility feed openings that include top left feed opening 112 and top center feed opening 114. In some implementations, the openings can be capped closed and an electrician selectively removes one or more caps when installing the electrical panel. The bottom of the panel can assembly 100 includes a bottom center feed opening 115. Bottom center feed opening 115 is part of a bottom utility access 116.

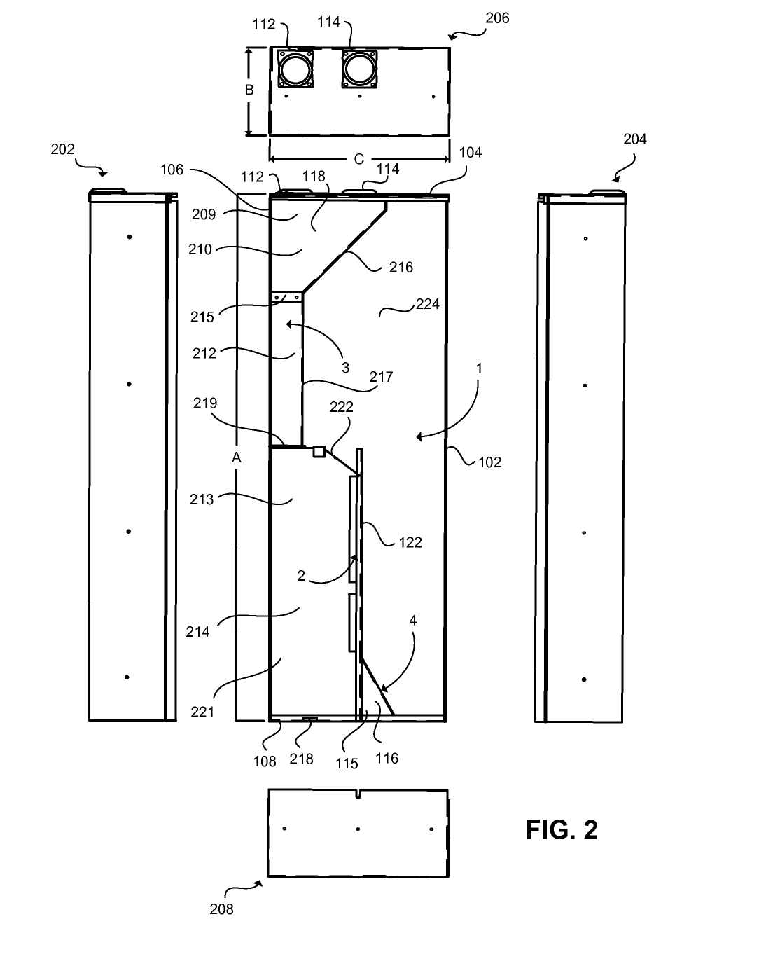

Bottom utility access 116 separates the utility wiring from wiring in load center space 120. Bottom utility access 116 is bolted or riveted onto utility area barrier 122 and/or sidewall 108. The utility feed can enter panel can assembly 100 through bottom center feed opening 115, and extend through an opening in utility area barrier 122 to continue through a bottom portion of raceway 118 to where the meter socket is located. Panel can assembly 100 includes a bottom left feed opening, which is not visible in FIG. 1 but is illustrated in FIG. 2.

An electrician can choose to insert a utility feed through a top left feed opening 112 and/or a top center feed opening 114 at the top of the panel can assembly 100 (e.g., sidewall 104). This utility feed is typically from an overhead service. The utility feed openings may be capped closed when not in use. Top center feed opening 114 is located substantially equidistant from both sidewall 102 and sidewall 106. Note that existing electrical panels do not have two openings on each of the top and bottom sides of the electrical panel.

At the bottom of the panel can assembly 100 (e.g., sidewall 108) an electrician can insert a utility feed through the bottom left feed opening and/or bottom center feed opening 115 (e.g., at bottom utility access 116). This utility feed is typically from an underground service.

Panel can assembly 100 also includes a distribution panel cover 124 that is attached to housing 101 with mounting bracket 126. In one implementation, distribution panel cover 124 is mounted at least two inches away from housing 101 to allow for one or more busbars to be raised higher, thereby facilitating the addition of top center feed opening 114. Utility wires that enter top center feed opening 114 can go under the elevated busbar toward the meter socket. Note that other wiring can also be inserted underneath the elevated busbar.

In some implementations, panel can assembly 100 has no other openings except for the top left feed opening, the top center feed opening, the bottom center feed opening, and the bottom left feed opening. The sides and/or bottom of panel can assembly 100 do not have any additional openings other than the openings illustrated in the figures. Additional openings can create problems with metal being exposed in the energized areas and overlapping holes conflicting with the holes that are needed for a particular installation. Instead, an electrician can drill only the holes that are absolutely needed for installing an electrical panel.

FIG. 2 presents a plan view of the panel can assembly 100 with side and end elevations, in accordance with an embodiment of the present invention. The different parts of panel can assembly 100 are clearly depicted in this illustration, including parts 1-4. As illustrated in FIG. 2, left side elevation 202 depicts an eye-level view of the left side of housing 101 including sidewall 106. Right side elevation 204 depicts an eye-level view of the right side of housing 101 including an eye-level view of sidewall 102. Top end elevation 206 depicts an eye-level view of the top side of housing 101 including sidewall 104, and bottom end elevation 208 depicts an eye-level view of the bottom side of housing 101 including sidewall 108. Note that generally end elevations are eye-level views of an object from the position of a vertical plane beside an end of the object, while side elevations are eye-level views of the side of the object from the position of a vertical plane beside the side of the object.

An electrician can use the panel can assembly 100 to install an electrical panel that can accommodate either an overhead feed or an underground feed. For an overhead feed, the electrician can extend utility wires through an opening on top utility access 209. For an underground feed, the electrician can extend utility wires through a bottom left feed opening or bottom center feed opening 115.

For an overhead feed, an electrician can extend utility wires through top left feed opening 112 and/or top center feed opening 114. Top left feed opening 112 and top center feed opening 114 are part of a top utility access 209, and both can accommodate an overhead feed. A utility feed entering through top left feed opening 112 can extend straight through top utility access 209, which includes a section 210 and a section 212, and down to a meter located approximately at location 213. Section 210 is defined (e.g., surrounded) by sidewall 106, a connection area 215, interior wall 216, and sidewall 104. Section 212 is defined (e.g., surrounded) by sidewall 106, connection area 215, interior wall 217, and interior wall 219. Note that interior wall 219 has an opening to allow the utility feed to extend through it.

An interior wall 216 is disposed at a 45° angle with respect to interior wall 217 so as to allow a utility feed to extend through raceway 118 of the electrical panel at an angle. In some implementation variations, interior wall 216 is disposed at some other angle (e.g., between 30-65 degrees, such as 30°, 50° or 60°, or some other arbitrary angle) with respect to interior wall 217. Note that raceway 118 includes top utility access 209, which includes section 210 and section 212. Raceway 118 also includes section 214. Section 214 is defined by utility area barrier 122, an interior wall 222, interior wall 219, sidewall 106, and sidewall 108. The utility wires may extend through section 210 and down to a meter socket underneath raceway 118 at location 213. An electrician can push a utility wire down through raceway 118 to the meter socket.

Panel can assembly 100 includes a bottom left feed opening 218 located at the bottom of panel can assembly 100 and a bottom utility access 116. Depending on the specific requirements of a particular installation, electricians can choose to insert the utility feed through bottom left feed opening 218 and/or bottom utility access 116. If the service entrance is underground, the electrician may choose to insert a utility feed through one of the openings at the bottom of panel can assembly 100.

A utility feed entering through bottom utility access 116 extends through an opening on utility area barrier 122 and into a utility section 221. Utility section 221 is part of raceway 118. Utility section 221 includes sections 210, 212, and 214. The utility feed can be connected to a meter (e.g., meter socket) at location 213. A utility feed entering through bottom left feed opening 218 enters utility wiring raceway 118 and can be connected to a meter (e.g., meter socket) at location 213. The wires leaving the bottom of the meter extend through a channel and continue to a main breaker at approximately location 224.

Note that in some implementations the top left feed opening 112 is aligned with the bottom left feed opening 218 such that a line drawn between the center of the two openings is substantially parallel to the left sidewall (or the right sidewall) of the panel can assembly 100. The top center feed opening may also be aligned with the bottom center feed opening such that a line drawn between the center of the two openings is substantially parallel to a left sidewall (or a right sidewall) of the housing.

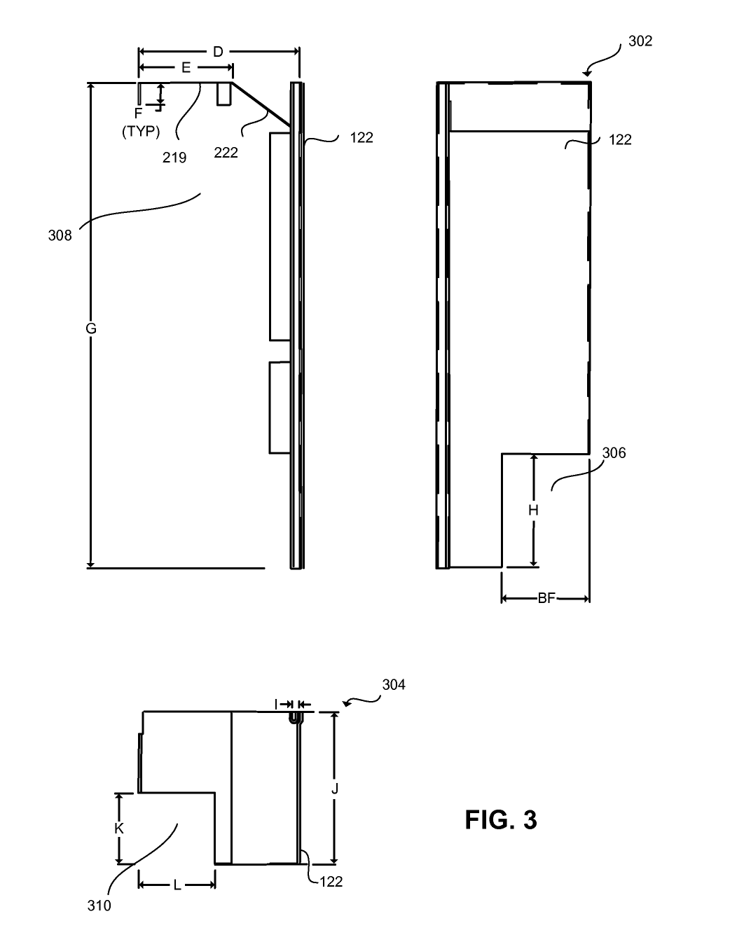

FIG. 3 presents a plan view of the utility area barrier 122 with side and end elevations, in accordance with an embodiment of the present invention. Utility area barrier 122 is labeled as part 2 in FIG. 1. Utility area barrier 122 separates the utility wiring from load center space 120 for holding circuit breakers and branch circuits, and is one of the boundaries of raceway 118. As illustrated in FIG. 3, side elevation 302 depicts an eye-level view of utility area barrier 122 from the position of a vertical plane beside the right side of utility area barrier 122. End elevation 304 depicts an eye-level view of section 214 from the position of a vertical plane beside the top end of utility area barrier 122.

Note that for the measurements disclosed herein the word “typical” after a measurement means that all the same parts have the same measurement as the disclosed measurement.

In one implementation, the dimensions for utility area barrier 122 can be D=7.268, E=4.232, F=0.980 (typical), and G=22.060. The dimensions for side elevation 302 can be H=5.149 and BF=4.000, and the dimensions for end elevation 304 can be I=0.313, J=6.938, K=3.250, and L=3.440. Note that all dimensions are in inches.

H & BF are example dimensions of an opening 306 that a utility feed (e.g., entering through bottom utility access 116) can extend through to section 308. Note that system 308 is a portion of utility section 214 that is partially depicted (e.g., the boundaries are not all depicted). K & L are example dimensions of an opening 310 that a utility feed (e.g., entering through bottom left feed opening 218) can extend through to section 308.

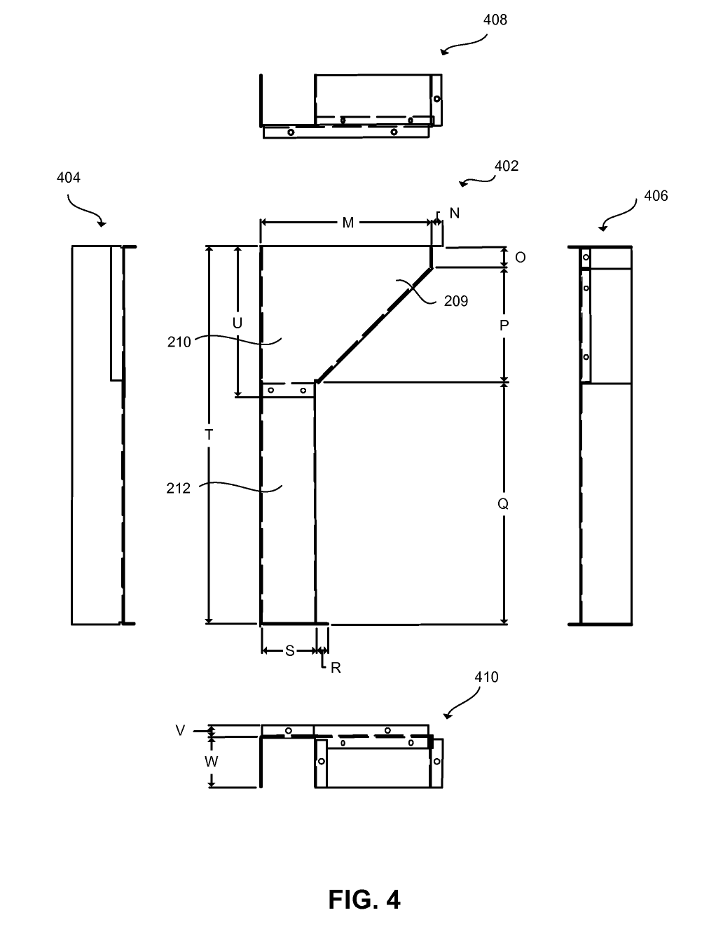

FIG. 4 presents a plan view of an assembled top utility access 209 with side and end elevations, in accordance with an embodiment of the present invention. The top utility access is labeled as part 3 in FIG. 1, and includes section 210 and section 212. FIG. 4 includes illustrations of a plan view 402 of top utility access 209, side elevation 404, side elevation 406, end elevation 408, and end elevation 410. Utility feeds can extend through top utility access 209, which includes section 210 and section 212, to reach the meter socket.

Side elevation 404 depicts an eye-level view of top utility access 209 from the position of a vertical plane beside the left side of top utility access 209. Side elevation 406 depicts an eye-level view of top utility access 209 from the position of a vertical plane beside the right side of top utility access 209. End elevation 408 depicts an eye-level view of top utility access 209 from the position of a vertical plane beside the top end of top utility access 209. End elevation 410 depicts an eye-level view of top utility access 209 from the position of a vertical plane beside the bottom end of top utility access 209.

In one implementation, the dimensions for top utility access 209 can be M=11.107, N=0.675, O=1.311, P=7.470, Q=15.671, R=0.719, S=3.520, T=24.422, and U=9.790. The dimensions for end elevation 410 can be V=0.750 and W=3.30. Note that all dimensions are in inches.

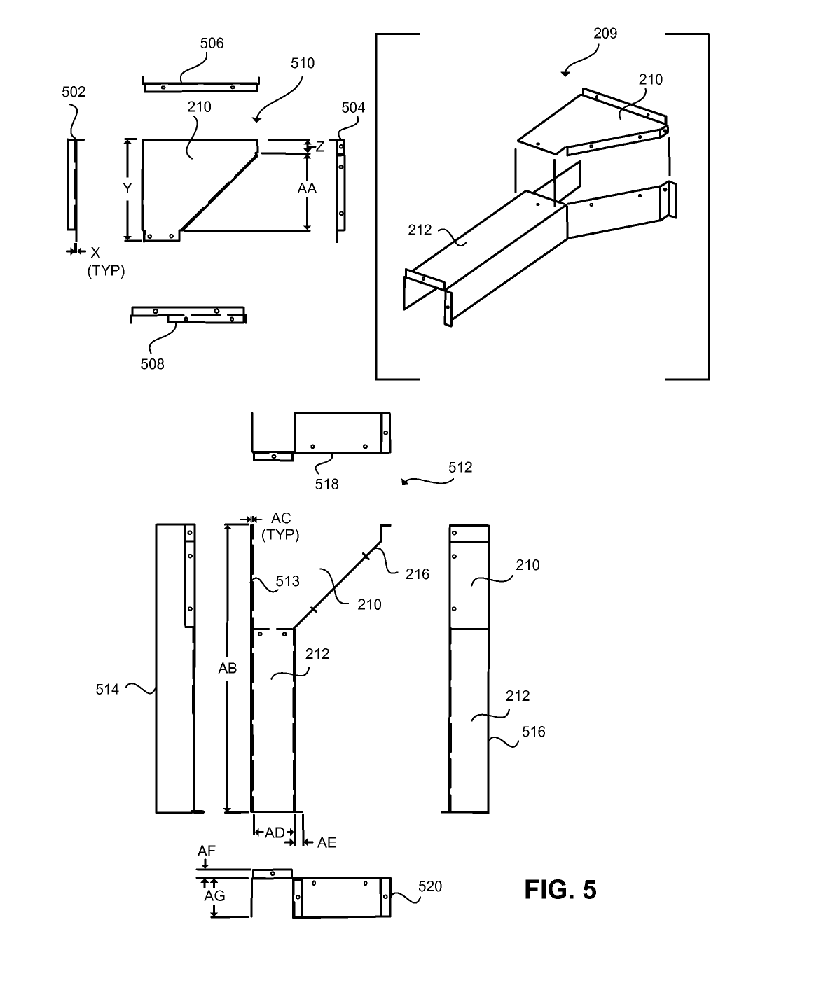

FIG. 5 presents a perspective view of an exploded top utility access 209 with plan view and elevations of two parts, in accordance with an embodiment of the present invention. Top utility access 209 is labeled as part 3 in FIG. 1, and includes sections 210 and 212.

FIG. 5 depicts side elevations 502, 504 and end elevations 506, 508 of section 210, and a plan view 510. FIG. 5 also depicts a plan view 512 of section 212 with a portion 513 of sidewall 106 and interior wall 216 with side elevations 514, 516 and end elevations 518, 520.

Side elevation 502 depicts an eye-level view of section 210 from the position of a vertical plane beside the left side of section 210. Side elevation 504 depicts an eye-level view of section 210 from the position of a vertical plane beside the right side of section 210. End elevation 506 depicts an eye-level view of section 210 from the position of a vertical plane beside the top end of section 210. End elevation 508 depicts an eye-level view of section 210 from the position of a vertical plane beside the bottom end of section 210.

Side elevation 514 depicts an eye-level view of section 212 and interior wall 216 from the position of a vertical plane beside the left side of section 212 and interior wall 216. Side elevation 516 depicts an eye-level view of section 212 and interior wall 216 from the position of a vertical plane beside the right side of section 212 and interior wall 216. End elevation 518 depicts an eye-level view of section 212 and interior wall 216 from the position of a vertical plane beside the top end of section 212 and interior wall 216. End elevation 520 depicts an eye-level view of section 212 and interior wall 216 from the position of a vertical plane beside the bottom end of section 212 and interior wall 216.

In one implementation, the dimensions can be X=0.062 (typical), Y=9.790, Z=1.311, and AA=7.470. The dimensions can be AB=24.527, AC=0.062 (typical), AD=3.520, and AE=0.0719. The dimensions can be AF=0.750, and AG=3.300. Note that all dimensions are in inches.

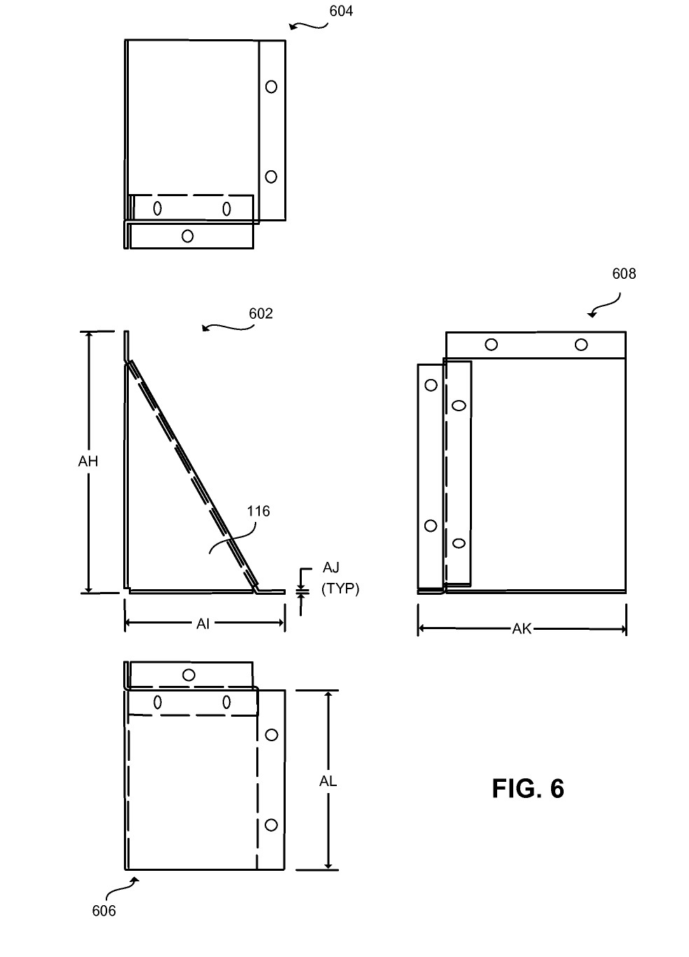

FIG. 6 presents a plan view of assembled bottom utility access 116 with side and end elevations, in accordance with an embodiment of the present invention. Bottom utility access 116 is labeled as part 4 in FIG. 1. FIG. 6 depicts a plan view 602, end elevations 604, 606 and side elevation 608 of bottom utility access 116.

End elevation 604 depicts an eye-level view of bottom utility access 116 from the position of a vertical plane beside the top end of bottom utility access 116. End elevation 606 depicts an eye-level view of bottom utility access 116 from the position of a vertical plane beside the bottom end of bottom utility access 116. Side elevation 608 depicts an eye-level view of bottom utility access 116 from the position of a vertical plane beside the right side of bottom utility access 116.

In one implementation, the dimensions for bottom utility access 116 are AH=5.814, AI=3.552, and AJ=0.062 (typical). In an implementation, the dimensions are AK=4.625, and AL=4.000. Note that all dimensions are in inches.

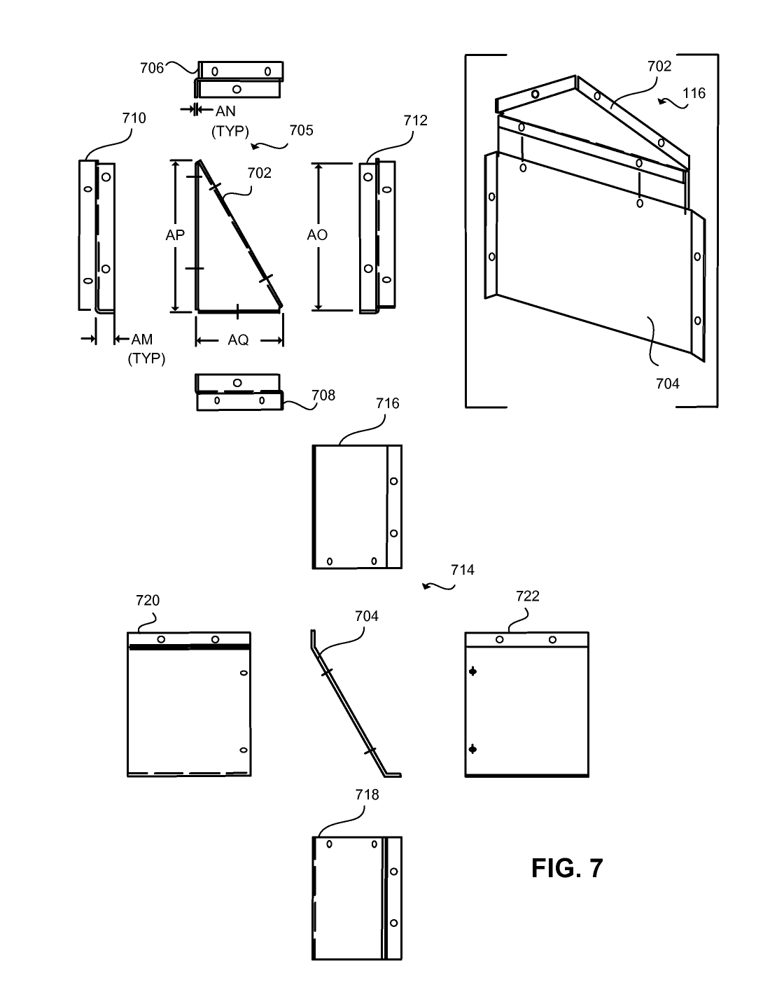

FIG. 7 presents a rotated, exploded perspective view of bottom utility access 116 with plan view and elevations of two parts, in accordance with an embodiment of the present invention. Bottom utility access 116 is labeled as part 4 in FIG. 1.

Bottom utility access 116 includes a triangle 702 and a bottom separator 704. FIG. 7 depicts a plan view 705, end elevations 706, 708 and side elevations 710, 712 of triangle 702, which forms part of bottom utility access 116. FIG. 7 also depicts a plan view 714, end elevations 716, 718 and side elevations 720, 722 of bottom separator 704, which forms part of bottom utility access 116.

End elevation 706 depicts an eye-level view of triangle 702 from the position of a vertical plane beside the top end of triangle 702. End elevation 708 depicts an eye-level view of triangle 702 from the position of a vertical plane beside the bottom end of triangle 702. Side elevation 710 depicts an eye-level view of triangle 702 from the position of a vertical plane beside the left side of triangle 702. Side elevation 712 depicts an eye-level view of triangle 702 from the position of a vertical plane beside the right side of triangle 702.

End elevation 716 depicts an eye-level view of bottom separator 704 from the position of a vertical plane beside the top end of bottom separator 704. End elevation 718 depicts an eye-level view of bottom separator 704 from the position of a vertical plane beside the bottom end of bottom separator 704. Side elevation 720 depicts an eye-level view of bottom separator 704 from the position of a vertical plane beside the left side of bottom separator 704. Side elevation 722 depicts an eye-level view of bottom separator 704 from the position of a vertical plane beside the right side of bottom separator 704.

In one implementation, the dimensions for bottom utility access 116 are AM=0.625 (typical), AN=0.062 (typical), AO=4.973, AP=5.159, and AQ=2.948. Note that all dimensions are in inches.

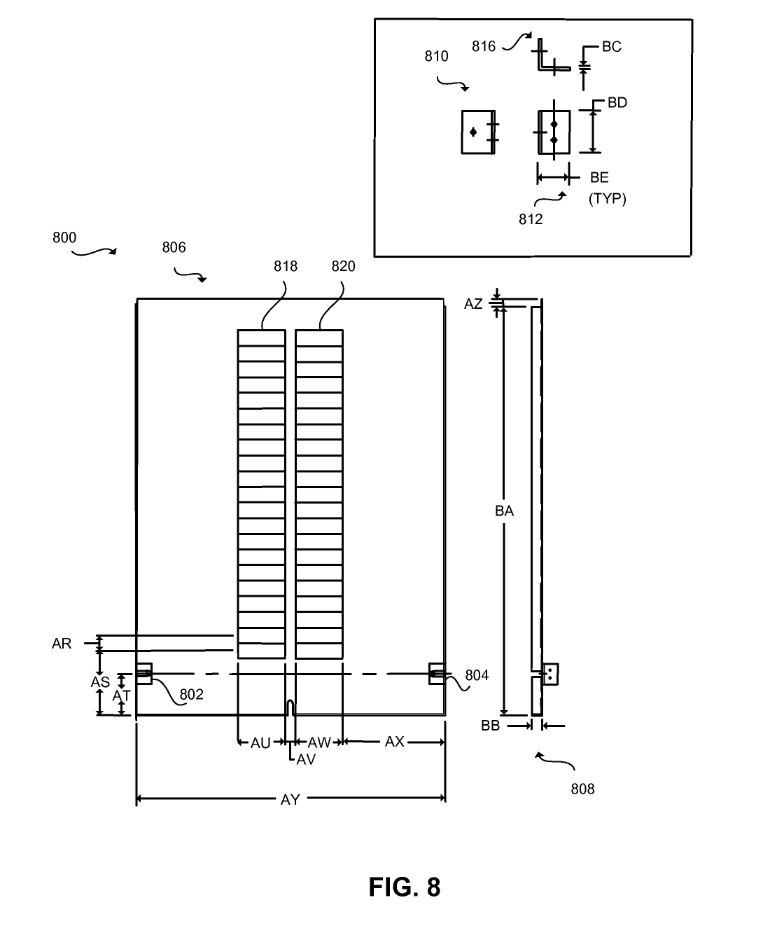

FIG. 8 presents a plan view of a distribution panel cover 800 with mounting brackets and plan view and elevations of the two parts, in accordance with an embodiment of the present invention. The illustrated distribution panel cover with mounting brackets is an example of distribution panel cover 124 labeled as part 5 in FIG. 1. Distribution panel cover 800 attaches to housing 101 with mounting brackets 802, 804.

FIG. 8 depicts a plan view 806 and elevation 808 for distribution panel cover 800, and plan views 810, 812 and elevation 816 of mounting bracket 802. Distribution panel cover 800 includes multiple detachable twistouts 818, 820. The electrician can remove some of the twistouts from twistouts 818, 820 after installing circuit breakers, so that the circuit breakers are exposed through the distribution panel cover 800.

Elevation 808 depicts an eye-level view of distribution panel cover 800 from the position of a vertical plane beside the right side of distribution panel cover 800. Elevation 816 depicts an eye-level view of mounting bracket 802 from the position of a vertical plane beside the bottom end of mounting bracket 802.

Distribution panel cover 800 is installed at least two inches away from housing 101 using mounting brackets 802, 804. Installing the distribution panel cover 800 at least two inches away from housing 101 allows for raising one or more busbars off of base 110. In some implementations, one or more busbars may be raised to at least two inches off of base 110. The additional clearance under the busbars allows the utility wires entering through top center feed opening 114 to extend underneath the busbars toward the meter socket, and also allows room for other wires, such as wires extending toward the circuit breakers. Note that conventional busbars typically only allow a half-inch of clearance.

In one implementation, the dimensions for the distribution panel cover are AR=0.750, AS=3.093, AT=2.000, AU=2.250, AV=0.500, AW=2.250, AX=4.903, AY=14.813, AZ=0.386, BA=19.590, and BB=0.500. The dimensions for the mounting bracket can be BC=0.062, BD=1.000, and BE=0.750 (typical). Note that all dimensions are in inches.

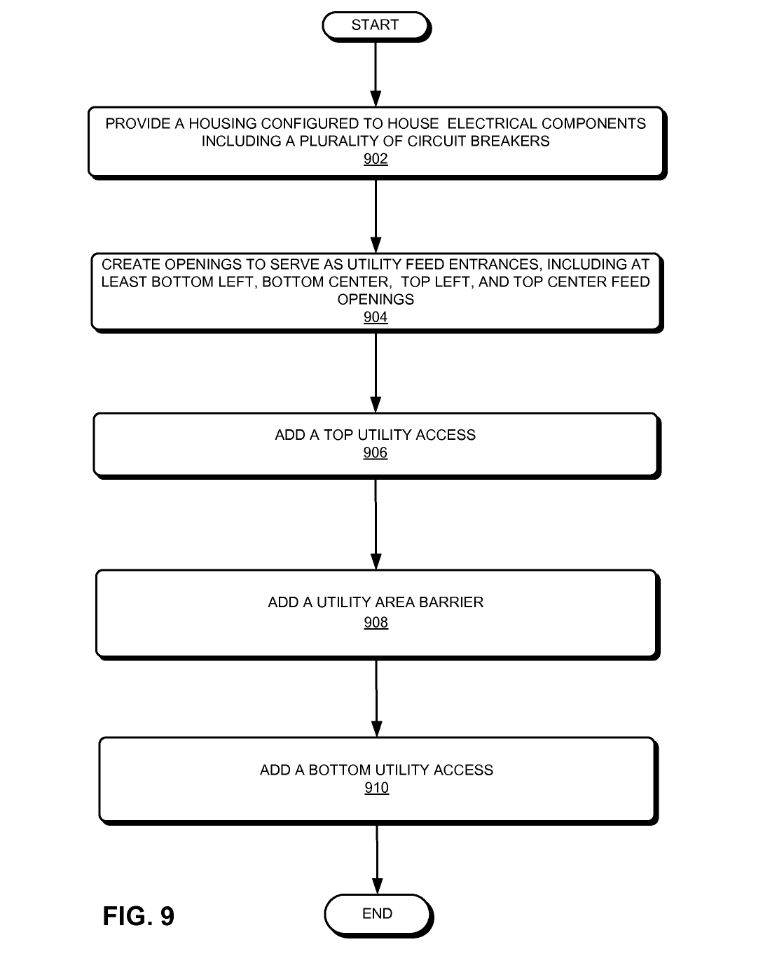

FIG. 9 presents a flowchart illustrating a process of assembling an electrical panel, in accordance with an embodiment of the present invention. During operation, the manufacturer provides a housing configured to house one or more electrical components including a plurality of circuit breakers (operation 902). The manufacturer then creates a plurality of openings on the housing. The plurality of openings serve as utility feed entrances, and the openings are disposed on the housing to allow for one or more electrical service wiring to enter the housing. The openings include at least a bottom left feed opening, a bottom center feed opening, a top left feed opening, and a top center feed opening (operation 904). The top left feed opening and the bottom left feed opening are each positioned on opposite sidewalls of the housing, and the top center feed opening and bottom center feed opening are likewise each positioned on opposite sidewalls of the housing.

The manufacturer may also add, to the electrical panel, a top utility access defined by a plurality of interior walls including a dividing wall disposed so as to form an angle (e.g., a 45° angle) with a wall parallel to a sidewall disposed along the length of the electrical panel (operation 906). A distribution panel cover may be added that can be mounted at least two inches away from the housing to allow for installation of an elevated busbar.

The manufacturer may also add, to the electrical panel, a utility area barrier that separates the utility feed from a load center space for holding branch circuits and/or circuit breakers (operation 908). The utility area barrier may include an opening to allow extending a utility feed from the bottom center feed opening to a utility area where a meter socket is located.

The manufacturer may also add, to the electrical panel, a bottom utility access (operation 910). The bottom center feed opening is part of the bottom utility access, and may be separated from the load center space for holding branch circuits and/or circuit breakers by an interior wall fastened to the utility area barrier and a sidewall of the housing.

The above description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

What is claimed is:

1. An electrical panel comprising:
a housing configured to house one or more electrical components including a plurality of circuit breakers, the housing with a plurality of openings serving as utility feed entrances, the openings being positioned on the housing to allow for one or more electrical service wiring to enter the housing, the housing including at least a bottom left feed opening, a bottom center feed opening, a top left feed opening, and a top center feed opening, wherein the top left feed opening and the bottom left feed opening are each positioned on opposite sidewalls of the housing, and the top center feed opening and bottom center feed opening are each positioned on opposite sidewalls of the housing.

2. The electrical panel of claim 1, further comprising a top utility access defined by a plurality of interior walls including a dividing wall disposed so as to form an angle with a wall parallel to a sidewall disposed along the length of the electrical panel.

3. The electrical panel of claim 1, wherein the angle is approximately 45 degrees.

4. The electrical panel of claim 1, wherein a distribution panel cover is mounted at least two inches away from the housing to allow for installation of an elevated busbar.

5. The electrical panel of claim 1, further comprising a utility area barrier that separates the utility feed from a load center space for holding branch circuits and/or circuit breakers; and the utility area barrier includes an opening to allow extending a utility feed from the bottom center feed opening to a utility area where a meter socket is located.

6. The electrical panel of claim 1, wherein the bottom center feed opening is part of a bottom utility access and separated from a load center space for holding branch circuits and/or circuit breakers by an interior wall fastened to a utility area barrier and a sidewall of the housing.

7. The electrical panel of claim 1, further comprising a raceway to allow the one or more electrical service wiring to extend through the housing from one of the two openings on the top sidewall, or from one of the two openings on the bottom sidewall, to a meter socket.

8. The electrical panel of claim 1, wherein the electrical panel is capable of being semi-flush mounted or surface mounted.

9. The electrical panel of claim 1, wherein the top left feed opening is aligned with the bottom left feed opening such that a line drawn between the center of the two openings is substantially parallel to a left sidewall or a right sidewall of the housing.

10. The electrical panel of claim 1, wherein the top center feed opening is aligned with the bottom center feed opening such that a line drawn between the center of the two openings is substantially parallel to a left sidewall or a right sidewall of the housing.

11. The electrical panel of claim 1, wherein the electrical panel has no other openings on sidewalls except for the top left feed opening, the top center feed opening, the bottom center feed opening, and the bottom left feed opening.

12. A method for assembling an electrical panel, the method comprising:
providing a housing configured to house one or more electrical components including a plurality of circuit breakers; and
creating a plurality of openings on the housing, the plurality of openings serving as utility feed entrances, the openings being positioned on the housing to allow for one or more electrical service wiring to enter the housing, the housing including at least a bottom left feed opening, a bottom center feed opening, a top left feed opening, and a top center feed opening, wherein the top left feed opening and the bottom left feed opening are each positioned on opposite sidewalls of the housing, and the top center feed opening and bottom center feed opening are each positioned on opposite sidewalls of the housing.

13. The method of claim 12, further comprising adding, to the electrical panel, a top utility access defined by a plurality of interior walls including a dividing wall disposed so as to form an angle with a wall parallel to a sidewall disposed along the length of the electrical panel.

14. The method of claim 12, wherein the angle is approximately 45 degrees.

15. The method of claim 12, wherein a distribution panel cover is mounted at least two inches away from the housing to allow for installation of an elevated busbar.

16. The method of claim 12, further comprising adding, to the electrical panel, a utility area barrier that separates the utility feed from a load center space for holding branch circuits and/or circuit breakers; and the utility area barrier includes an opening to allow extending a utility feed from the bottom center feed opening to a utility area where a meter socket is located.

17. The method of claim 12, wherein the bottom center feed opening is part of a bottom utility access and separated from a load center space for holding branch circuits and/or circuit breakers by an interior wall fastened to a utility area barrier and a sidewall of the housing.

18. The method of claim 12, wherein the electrical panel is capable of being semi-flush mounted or surface mounted.

19. The method of claim 12, wherein the top left feed opening is aligned with the bottom left feed opening such that a line drawn between the center of the two openings is substantially parallel to a left sidewall or a right sidewall of the housing.

20. The method of claim 12, wherein the electrical panel has no other openings on sidewalls except for the top left feed opening, the top center feed opening, the bottom center feed opening, and the bottom left feed opening.
